(19) United States
(12) Patent Application Publication
(10) Pub. No.: US 2010/0287751 A1
(43) Pub. Date: Nov. 18, 2010

(54) METHOD FOR PRODUCING FUNCTIONAL COMPOSITE MATERIAL

(75) Inventors: Hiroshi Asanuma, Chiba (JP); Naohiro Takeda, Chiba (JP); Takamitsu Chiba, Chiba (JP)

Correspondence Address: KNOBBE MARTENS OLSON & BEAR LLP, 2040 MAIN STREET, FOURTEENTH FLOOR, IRVINE, CA, 92614, US

(73) Assignee: NATIONAL UNIVERSITY CORPORATION CHIBA UNIVERSITY, CHIBA (JP)

(21) Appl. No.: 12/513,117

(22) PCT Filed: Oct. 31, 2007
(86) PCT No.: PCT/JP2007/071239

§ 371 Date: Jun. 21, 2010

(30) Foreign Application Priority Data
Nov. 1, 2006 (JP) 2006-298052

(51) Int. Cl. H01L 41/22

(52) U.S. Cl. 29/25.35

(57) ABSTRACT

Disclosed is a method for more easily producing a functional composite material internally containing a piezoelectric fiber.

Specifically disclosed is a method for producing a functional composite material, wherein a hollow fiber is arranged in a groove of a first metal substrate having a groove, and then a second metal substrate and the first metal substrate are pressed together.

### TECHNICAL FIELD

The present invention relates to a method for producing functional composite material, especially relates to a method for producing functional composite material internally containing a piezoelectric element.

Even since a functional composite material adaptable to environmental changes by embedding various types of fiber or the like in a material and transforming it into a composite material was proposed, investigations have been carried out actively toward the realization thereof.

Examples of conventional technologies of embedding a fiber in a metal matrix material and transforming it into a composite material include Patent Document 1 ,2 and 3 described below.

Patent Document 1 described below discloses a technology of producing a functional composite material with an optical fiber embedded in a metal matrix material. Furthermore, Patent Document 2 described below discloses a technology of producing a functional composite material with a long-fiber reinforced composite material and short-fiber reinforced composite material embedded in a metal material.

Furthermore, Patent Document 3 described below discloses a functional composite material internally containing a piezoelectric fiber which has a metal core. The functional composite material is usable as a sensor or an actuator with good response.

### Patent Document 1: Japanese Patent Laid-Open No. 2001-82918(JP2001-82918A1)

### Patent Document 2: Japanese Patent Laid-Open No. 2002-283487(JP2002-283487A1)

### Patent Document 3: Japanese Patent Laid-Open No. 2003-328266(JP2003-328266A1)

Certainly, the functional composite material described in above-described Patent Document 3 is applicable to a sensor or an actuator, and useful.

However, as the functional composite material is extremely brittle, enough attention is needed for burying it in the metal substrate. Thus, it is not easy to manufacturing a functional composite material.

Further, as it is not easy to manufacturing a piezoelectric fiber, the cost will be high.

Therefore, it is an object of the present invention to provide an easier method for producing a functional composite material.

Inventors investigate the problems and found that the problems are resolved by placing a hollow piezoelectric fiber between metal substrates, melting the metal substrate and filling up the holly piezoelectric fiber with the metal.

### DISCLOSE OF THE INVENTION

The method for producing a functional composite material according to one means for achieving the above described object includes a step of placing a hollow fiber on a first metal substrate in which a groove is formed, a step of pressing a second metal substrate and the first metal substrate.

Furthermore, the above described means more preferably uses, but not limited to, a metal thin film layer is formed on the first metal substrate in which a groove is formed.

Furthermore, the above described means more preferably uses, but not limited to, a metal thin film layer is formed on the second metal substrate.

Furthermore, the above described means more preferably uses, but not limited to, a groove is formed on the second metal substrate, and the groove of the first metal substrate and the groove of the second metal substrate is corresponded in the step of pressing a second metal substrate and the first metal substrate.

Furthermore, the above described means more preferably uses, but not limited to, the groove has a wall edge portion and a open edge portion.

Furthermore, the above described means more preferably uses, but not limited to, the first substrate and the second substrate contain aluminium or aluminium alloy.

### BENEFIT OF THE INVENTION

As described above, it is possible to provide an easier method for producing a functional composite material.

### BEST MODE FOR CARRYING OUT THE INVENTION

Hereinafter, the detail of a mode of carrying out the present invention will be described. However this invention will be carried out by many modes. Thus this invention is not limited in the below-described embodiments and examples.

### EMBODIMENT 1

FIG. 1 shows steps of method for producing a functional composite material of this embodiment. As shown FIG. 1, the method for producing functional composite material of this embodiment includes a step of forming a metal thin film layer 2 on a first metal substrate 1 (FIG. 1(A)), a step of forming a groove on the first metal substrate 1 with the metal thin film layer 2 (FIG. 1(B)), a step of placing hollow fiber 4 on the groove 3 of the first metal substrate (FIG. 1(C)), and a step of pressing a second metal substrate 5 and the first metal substrate (FIG. 1(D)).

Further, in this description, the word, “first metal substrate” and “second substrate”, are used only for distinguishing one substrate from another substrate. They are not used for limitation of the component.

In this embodiment, many kinds of metal are applicable for the first metal substrate. Further, aluminum, magnesium, titanium, iron or nickel, or alloy which contains at least one of aluminum, magnesium, titanium, iron or nickel is preferable. Furthermore, aluminium or aluminium alloy is useful by the benefit of lightness and low price.

The thickness of the metal substrates is adjustable for each condition. However, the preferable thickness of the metal substrate is from 0.5 mm to 10 mm, and 2 mm or less is more preferable.

Many kinds of metal are applicable for the metal thin film layer 2, as long as the layer is melted in the step of pressing the first metal substrate and the second metal substrate and the melted metal fills up the hole of the hollow fiber. Further, copper, zinc or silicon, or alloy which contains at least one of copper, zinc or silicon is preferable, in the case that the first metal substrate 1 or the second metal substrate 5 contains aluminum. Furthermore, copper is more preferable because the combination of the copper and aluminum lowers the temperature of eutectic point and increases the bonding strength of the metal substrates.

The thickness of the metal thin film layer 2 is adjustable for each condition.

However, for avoiding breaking of the hollow piezoelectric fiber, the thickness range from 5 micrometer to 20 micrometer is preferable in case that the first metal substrate 1 contains aluminum and the metal thin film layer 2 contains copper. The thickness range from 10 micrometer to 15 micrometer is more preferable.

Furthermore, many methods are applicable for the step of forming metal thin film layer on the first metal substrate as long as they are able to achieve thin film layer with uniform thickness. For example, metal foil inserting, plating, deposition, sputtering or thermal spraying is preferable.

Furthermore, it is preferable that the metal thin film layer is formed on the second metal substrate 5 (see FIG. 2).

Many methods are applicable for the step of forming a metal thin film layer 2 on the first metal substrate. For example, plasticity process using steel string, cutting, electric discharge process or etching is preferable.

The depth of the groove is adjustable for each condition as long as it is able to placing the hollow fiber on the groove and avoiding breaking the hollow fiber in the pressing.

For example, the preferable range of the depth of the groove is larger from 10 micrometer to 100 micrometer than the outside diameter. Furthermore the more preferable range of the depth is larger from 10 micrometer to 50 micrometer than the outside diameter.

It is possible to avoid breaking the hollow fiber by the pressure in the step of pressing if the depth of the groove is 10 micrometer or more. On the other hand, if the depth of the groove is 100 micrometer or less, it is possible to avoid staying the excessive melted metal thin film layer in the substrate, and effectively fill the melted metal thin film layer into the hole of the hollow fiber.

The sectional shape of the groove is able to adopt many shapes as long as it is possible to avoid breaking of the hollow fiber and to combine the hollow fiber and the metal substrate. As shown in FIG. 1, U-like shape is preferable.

Furthermore, the plane shape of the groove is able to adopt many shapes as long as the shape of the groove is same as the shape of the hollow fiber. For example, line shape is preferable and straight line shape is more preferable.

FIG. 3 shows a plane view of the first substrate of the functional composite material of embodiment 1.

The number of the groove is not limited. It is possible that a plural number of the grooves are formed on the metal substrate.

Further, the depth of the groove means the distance between the surface plane of the first metal substrate and the bottom plane of the groove (if the groove is U-like groove, the bottom means the most deepest portion) (see FIG. 1(B)).

Further, it is preferable that the groove has a edge portion 31 which has a wall, and another edge portion 32 which is opened to the outside of said first substrate (see FIG. 3).

By this structure, the ratio of filling up hollow fiber 4 becomes higher, because the flow of melted metal is decided to one direction, in the step of pressing.

For the hollow fiber 4, many materials are applicable as long as the materials are piezoelectric materials. For example, a PZT fiber which contains an oxide of Pb, Ti or Zr is preferable.

For the hollow fiber 4, many kinds of sections are applicable as long as the hollow fiber is a tube. For example, circular shape, triangulate shape or square shape is preferable.

For filling the melted metal thin film layer into the hollow fiber, and avoiding forming an opening in the hollow fiber, it is preferable that the outside shape of the hollow fiber is similar to the inside shape of the hollow fiber. Further more it is more preferable that both of the shape are circular shape.

The preferable range of outside diameter of the hollow fiber is from 200 micrometer to 1000 micrometer. Furthermore, the more preferable range is from 400 micrometer to 800 micrometer, because the hollow fiber within the range is easily obtainable.

The thickness of the hollow fiber (the difference between the outside diameter and the inside diameter) is adjustable for each condition as long as the hollow fiber is not broken.

For example, the preferable range of the thickness of the hollow fiber is from 100 micrometer to 900 micrometer in the case that the outside diameter of the hollow fiber is in from 200 micrometer to 1000 micrometer. Further, for example, the more preferable range of the thickness of the hollow fiber is from 300 micrometer to 700 micrometer in the case that the outside diameter of the hollow fiber is in from 400 micrometer to 800 micrometer.

The arrangement of the hollow fiber 4 is adjustable for each condition, as long as it is possible to fill the melted metal thin film layer into the hole of the hollow fiber and to combine the two substrates.

It is preferable that one edge of the hollow fiber is in the plane of the first metal substrate and the other edge of the hollow fiber is protruded from the substrate (see FIG. 3).

By this arrangement, it is possible to discharge the excessive melted metal thin film layer from the substrate, certainly.

Many metals which are applicable for the first metal substrate 1 are applicable for the second metal substrate 5. Of course, it is possible the metal of the first metal substrate and the metal of the second metal substrate are same.

The pressure of the step of pressing the first metal substrate against the second metal substrate is adjustable as long as the first and second substrates are able to be combined.

For example, the range of the pressure of the step of pressing is preferable from 2 MPa to 4 MPa and more preferable from 2 MPa to 3 MPa.

At the pressure 2 MPa or more, the excessive remain of metal thin, film layer will be discharged from the substrates. The discharge will carry out stronger bonding.

Furthermore, at the pressure 4 MPa or less, it is able to combine the substrates without breaking of the hollow fiber, more certainly.

The temperature of the pressing the first metal substrate against the second metal substrate is adjustable for each condition such as the selection of the material. However, it is preferable that the temperature of the pressing is higher than the eutectic temperature of the first metal substrate and the metal thin film layer. Further, it is preferable that the temperature of the pressing is lower than the temperature of the melting point of the first metal substrate and the metal thin film layer.

For example the range of the temperature of the pressing is preferable from 550° C. to 650° C., in the case that the metal substrate contains aluminum and the metal thin film layer contains copper. The range of the temperature of the pressing is more preferable from 580° C. to 600° C. in the same condition.

If the temperature is 550° C. or more, it is possible to discharge the excessive melted metal thin film layer to outside of the substrate. Furthermore, by discharging, diffusion and plasticity flow, the two substrates combine strongly.

If the temperature is 650° C. or less, it is possible to avoid unnecessary melting of the aluminum, further avoid deforming the groove. Consequently, it is possible to avoid breaking the hollow fiber.

Further, the period of time for pressing is adjustable for each condition such as a selection of material or the temperature of the pressing, as long as it is possible to combine the metal substrate, and avoid breaking the hollow fiber. For example, from 5 minutes to 1 hour is preferable.

FIG. 4 shows a outline of the cross-sectional view of the functional composite material of embodiment 1.

By this embodiment, it is possible to melt the metal thin film layer by pressing the first metal substrate against the second substrate, and pour the melted metal thin film layer into the hollow fiber. Consequently, it is possible to produce a piezoelectric fiber having a metal core.

Therefore, it is possible to easily produce a functional composite material containing piezoelectric fiber having a metal core by using a hollow fiber, without breaking the hollow fiber.

It is possible that this functional composite material is usable as a sensor, by attaching a terminal and a voltmeter. Further, it is possible to use as an actuator, by inducing a voltage to this functional composite material. Furthermore, this functional composite material is also usable as other device.

### EMBODIMENT 2

In the method for producing a functional composite material of embodiment 1, the groove is formed only on the first metal substrate. However, the method for producing a functional composite material of this embodiment 2 is different from embodiment 1 in the groove that is also formed on the second metal substrate 2. Other steps are same as embodiment 1.

FIG. 5 shows a part of steps (it corresponds to the FIG. 1(D)) of method for producing a functional composite material of embodiment 2.

According to the embodiment 1, the thickness of the metal substrate 1 has to be thick sufficiently. However, in this embodiment, it is possible that the thickness of the metal substrate 1 is to be thinner.

Furthermore, in this case, “the thickness of groove” means the total thickness of the thickness of the groove formed on the first metal substrate 1 and the thickness of the groove formed on the second metal substrate 2.

Further, as described in embodiment 1, it is possible that the metal thin film layer 2 is formed on the second metal substrate 5 (see FIG. 6).

### EMBODIMENT 3

The method for producing a functional composite material is different from the embodiment 1 in the step of forming the groove on the substrate before forming metal thin film layer on the substrate. Other steps are almost same as embodiment 1.

FIG. 7 shows the steps of method for producing a functional composite material of embodiment 3.

The method for producing a functional composite material of this embodiment includes the steps, a step of forming a groove on a first metal substrate (FIG. 7(A)), a step of forming a metal thin film layer on the first metal substrate (FIG. 7(B)), a step of placing a hollow fiber in the groove formed on the first metal substrate (FIG. 7(C)), a step of pressing the first metal substrate against the second metal substrate (FIG. 7(D)).

The method of this embodiment has same benefit of embodiment 1.

The method of embodiment 1 has a benefit that strict consideration of the size of the groove is not necessary. On the other hand, the method of this embodiment has a benefit that it is possible to adjust the metal thin film layer and uniform it.

Further, in this embodiment, it is possible that the groove is formed on the second substrate 5, and the metal thin film layer is formed on the second metal substrate 5.

### Example

A functional composite material as the above-described embodiment was produced, and the function of the composite material was confirmed.

In this example, a functional composite material according to embodiment 1 was made. The first metal substrate (60 mm×30 mm×1.5 mm) was made of pure aluminum. A PZT fiber (outside diameter 50 micrometer, inside diameter 250 micrometer, length 50 mm) (smart material Inc. PZT5H2) was used as a hollow fiber.

First, a pure copper foil was formed on the first substrate. The thickness of the foil was 10 micrometer.

Next, SUS 304 stainless steel string was pressed against the first metal substrate and the U-Like groove was formed on the first metal substrate. The width of the groove was 530 micrometer and the depth of the groove was 530 micrometer.

Further, one edge of the groove is in the substrate plane and stands as a wall. On the other hand, the other edge of the groove is extended to the edge of the substrate (the edge of the groove is connected to outside of the substrate).

Next, as shown FIG. 3, the functional composite material was manufactured by pressing the first substrate and the second substrate at the condition of 2.2 MPa, 600 degree centigrade, 40 min. In the pressing, the one edge of the hollow fiber was formed being protruded.

FIG. 8 shows the SEM photograph of the cross-sectional view of the functional composite material of this example. As shown FIG. 8, the condition of the composite material is good without breaking of piezoelectric fiber and excessive remain of the insert material.

Further, after polarization process to the piezoelectric fiber, shock experiment was carried out for confirming that the produced functional composite material is applicable for a sensor. In the shock experiment, output voltage being generated from the shock by breaking a fragile material (The bend strength is 19 MPa) on the composite material was measured.

FIG. 9 shows the system of the experiment, and FIG. 10 shows the result of this experiment.

By this experiment, it is confirmed that this composite material generates the voltage against the shock from outside, and the hollow fiber embedded is able to function.

By this experiment, it is confirmed that it is easy to produce a functional composite material by this method. Because this experiment didn't use the piezoelectric fiber having metal core but uses the hollow fiber which is easily manufactured, it is possible to manufacture a piezoelectric fiber and produce the functional composite material at the same time.

Additionally, since it is confirmed that this composite material generates the voltage against the shock from outside, it is estimated that the composite material functions as an actuator by inducing the voltage to the composite material.

Further, another shock experiment was carried out. This shock experiment was carried out by using a sample block as shown FIG. 10. The sample block was manufactured by cutting above-manufactured composite materials into dice (3 mm×3 mm×3 mm), and coating with methacrylate resin (R=12.5 mm, height 30 mm, rodlike).

This shock experiment is carried out by observing the voltage generated between metal substrate and internally contained metal, when against the sample.

FIG. 11 shows the schematic view of experiment apparatus for another shock experiment of example 1. FIG. 12 shows the result of the second shock experiment of example 1.

For this experiment, a hollow guideline pipe (outside diameter 15 mm, inside diameter 11 mm, length 150 mm) was arranged on the sample block. Further a wooden rod (diameter 10 mm, length 100 mm, weight 4.7 g) was fallen into the hole of the guideline pipe.

By this experiment, the voltage response against the shock was appeared. It was confirmed that this composite material is usable as a sensor by this experiment.

### INDUSTRIAL APPLICABILITY

The functional composite material of the present invention, but not limited to, is applicable for a sensor or an actuator. Therefore, the functional composite material has industrial applicability.

### BRIEF DESCRIPTION OF THE DRAWINGS

FIG. 1 shows steps of method for producing a functional composite material of embodiment 1.

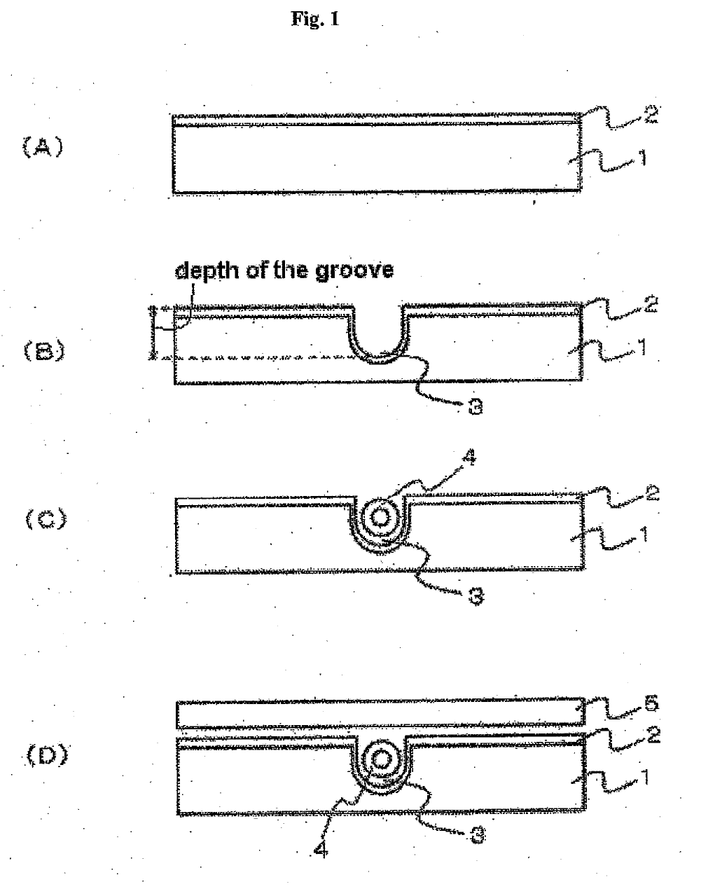

FIG. 2 shows steps of another method for producing a functional composite material of embodiment 1.

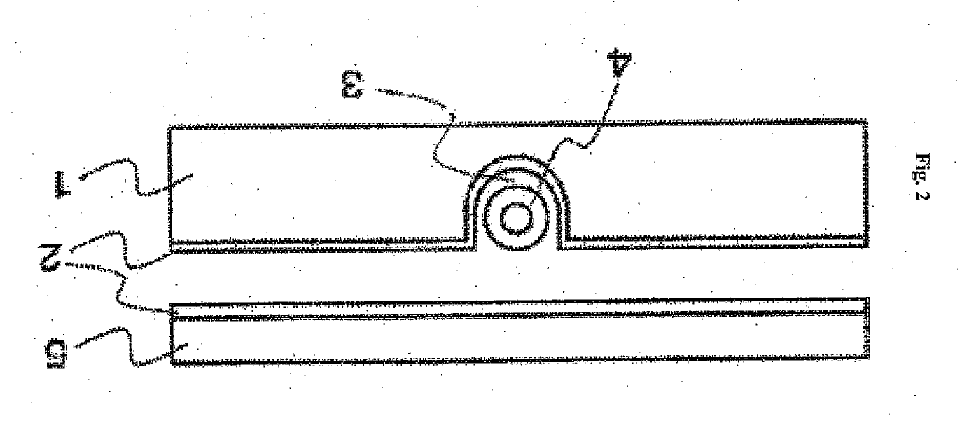

FIG. 3 shows a plane view of the first substrate of the functional composite material of embodiment 1.

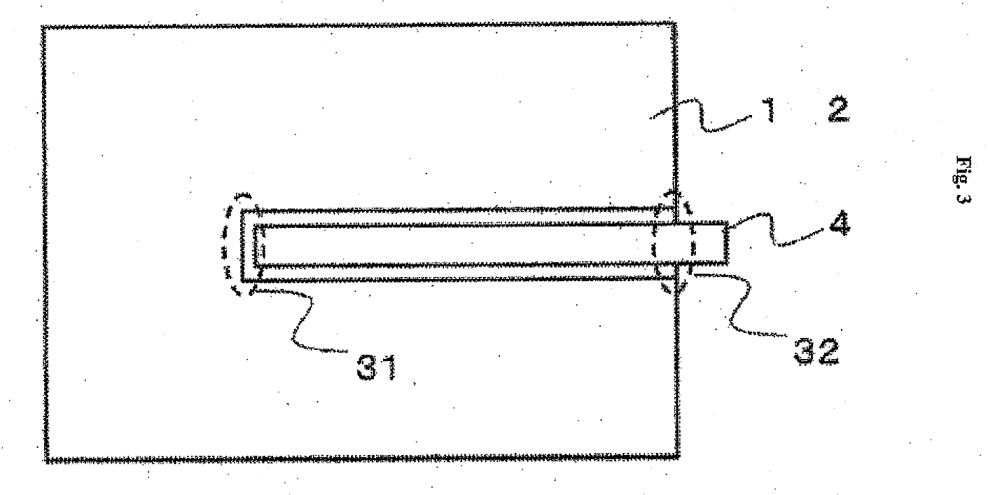

FIG. 4 shows a outline of the cross-sectional view of the functional composite material of embodiment 1.

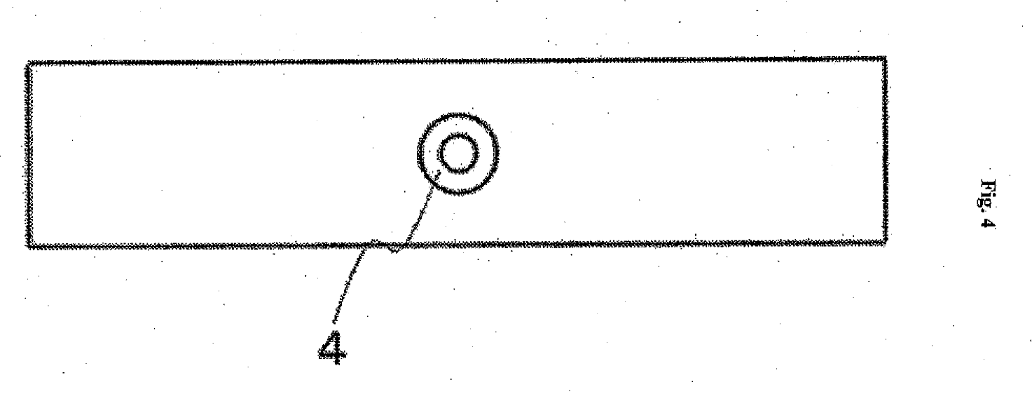

FIG. 5 shows a part of steps of method for producing a functional composite material of embodiment 2.

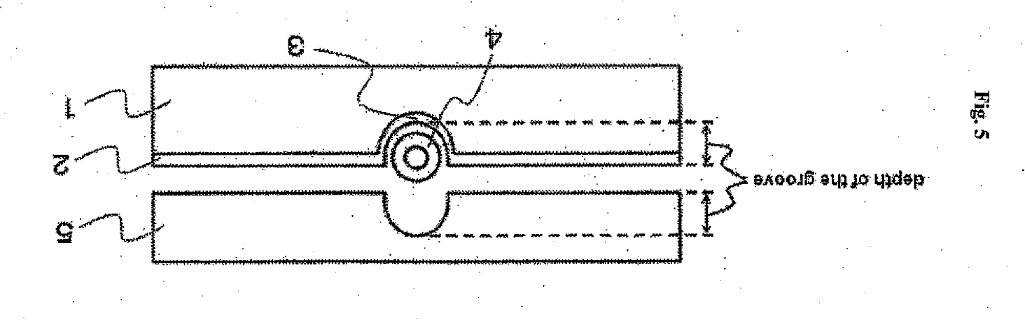

FIG. 6 shows steps of another method for producing a functional composite material of embodiment 2.

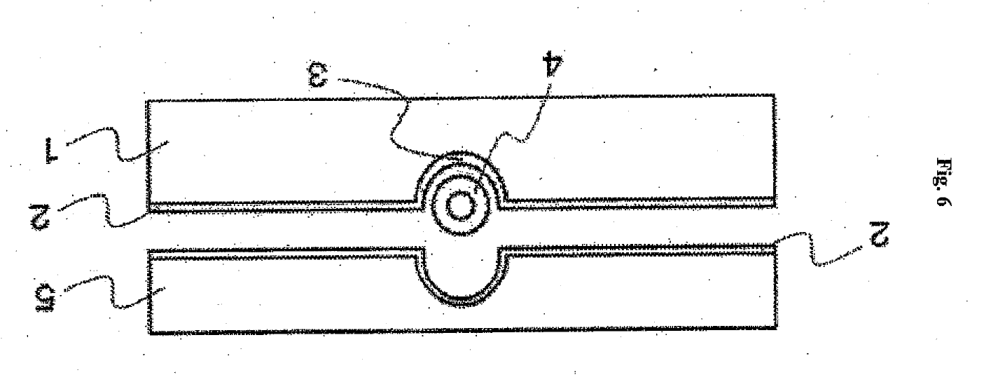

FIG. 7 shows steps of method for producing a functional composite material of embodiment 3.

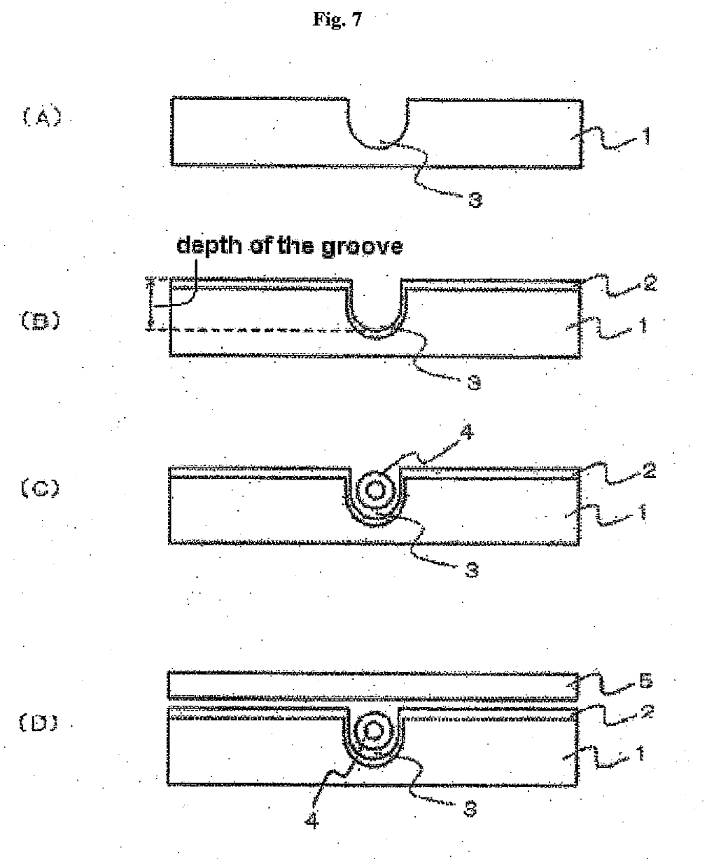

FIG. 8 shows the SEM photograph of the cross-sectional view of the functional composite material of example 1.

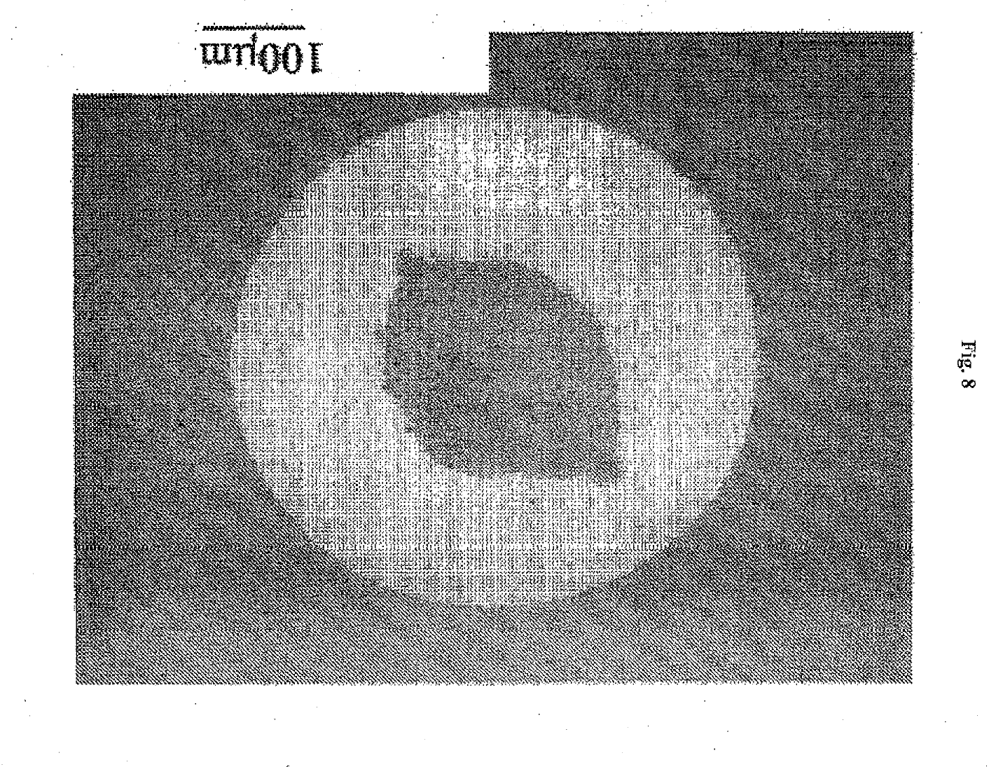

FIG. 9 shows the system of the experiment for confirming the function of the functional composite material of example 1.

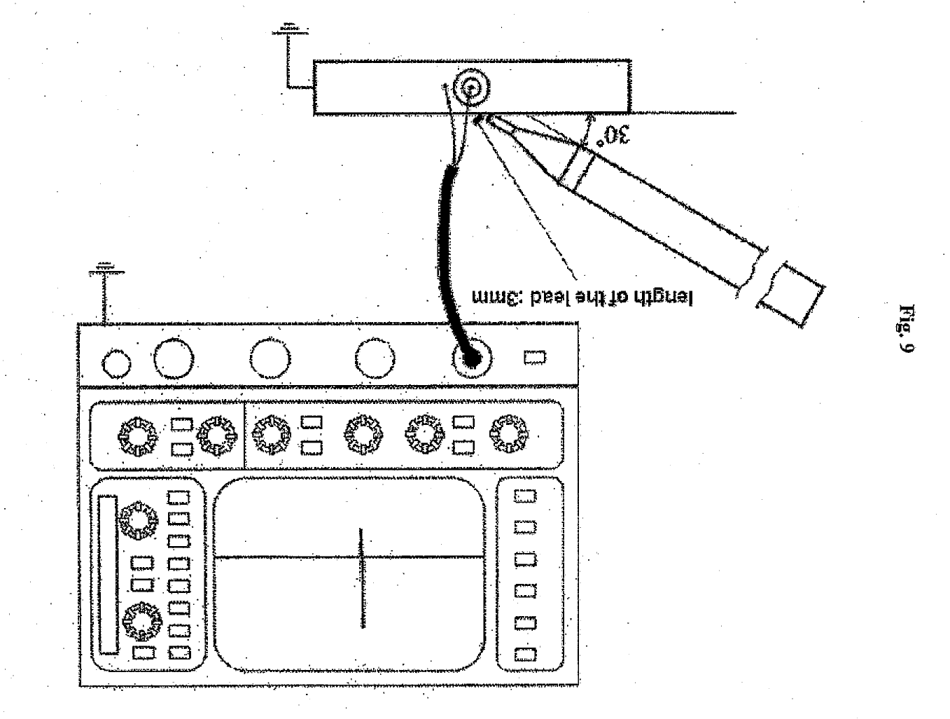

FIG. 10 shows the result of the experiment for confirming the function of the functional composite material of example 1.

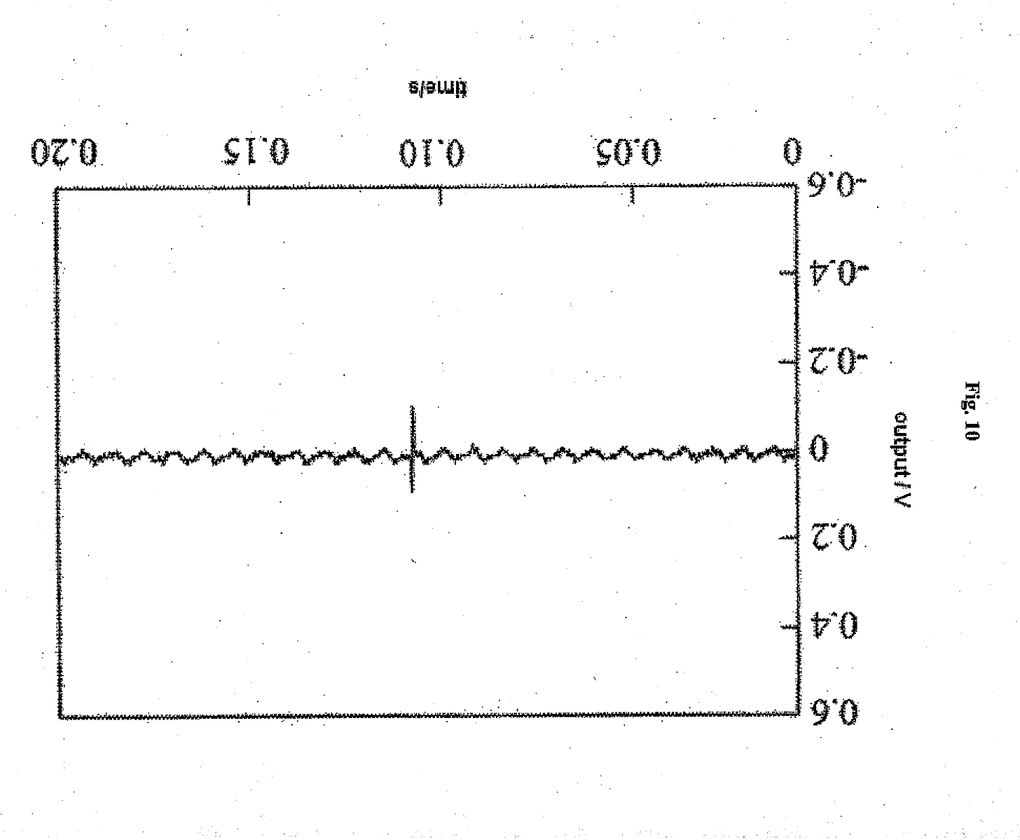

FIG. 11 shows the schematic view of sample for shock experiment of example 1.

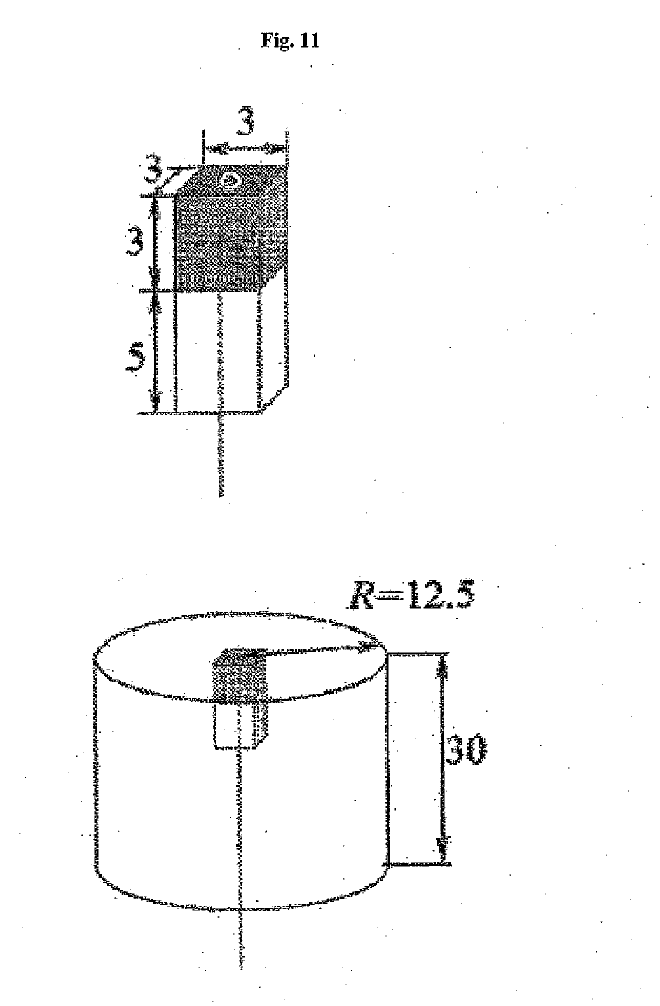

FIG. 12 shows the schematic view of experiment apparatus for shock experiment of example 1.

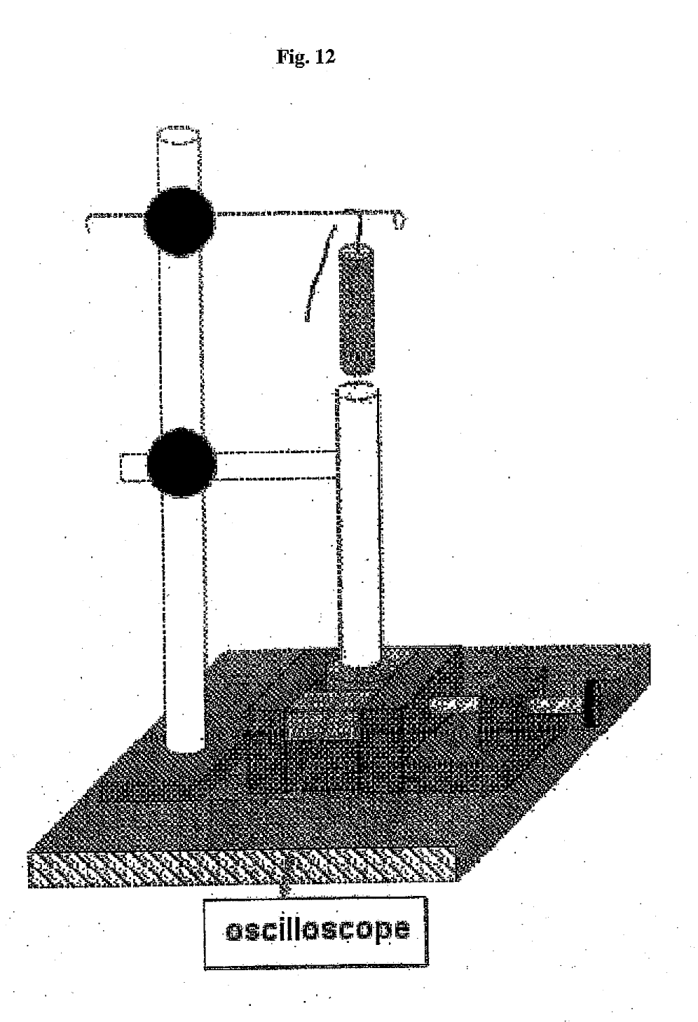

FIG. 13 shows the result of the shock experiment of example 1.

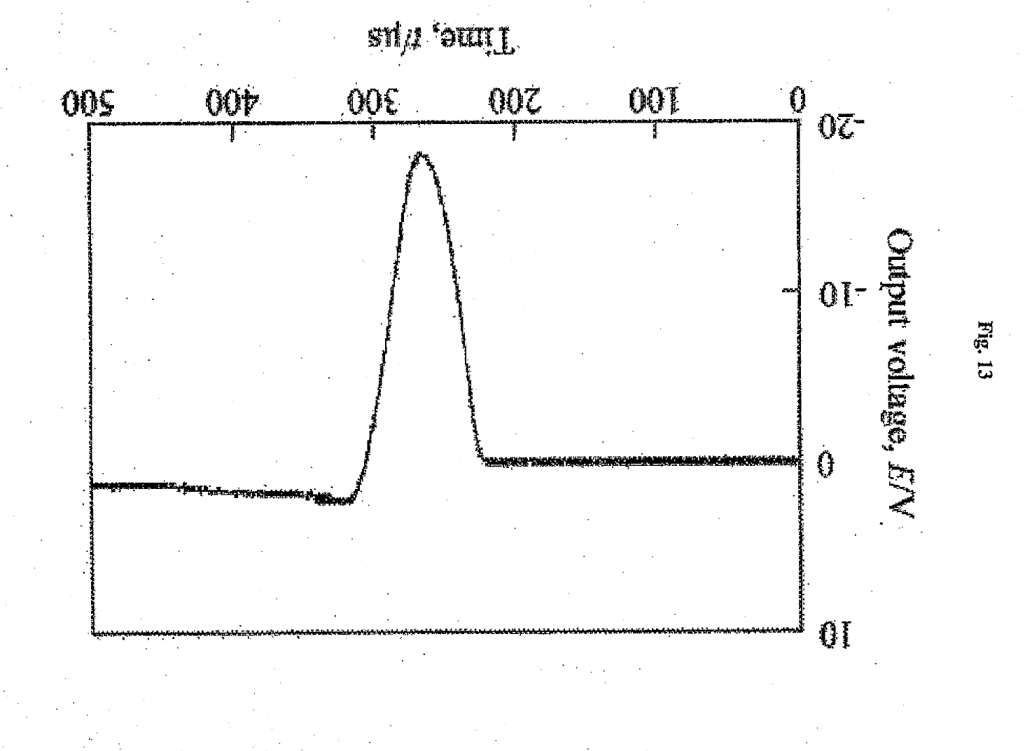

### DESCRIPTION OF SYMBOLS

1 . . . first metal substrate, 2 . . . metal thin film layer, 3 . . . groove, 4 . . . hollow fiber, 5 . . . second metal substrate, 31 . . . edge portion (of groove) having a wall, 32 . . . edge portion (of groove) opened to the outside of the substrate.

What is claimed is :

1. A method for a functional composite material includes the steps:
a step of arranging a hollow fiber on a groove which is formed on a first substrate; and
a step of pressing said first metal substrate and a second metal substrate.

2. The method according to claim 1, wherein a metal thin film layer is formed on said first substrate.

3. The method according to claim 2, wherein a metal thin film layer is formed on said second substrate.

4. The method according to claim 1, wherein a groove is formed on said second substrate;
and the position of said groove of said first metal substrate corresponds to the position of said groove of said second metal substrate in the step of pressing.

5. The method according to claim 1, wherein said groove has a first edge portion which has a wall, and another edge portion which is opened to the outside of said first substrate.

6. The method according to claim 1, wherein said first metal substrate and said second metal substrate contain aluminum or aluminum alloy.
